(19) United States
(12) Patent Application Publication
(10) Pub. No.: US 2012/0285523 A1
(43) Pub. Date: Nov. 15, 2012

(54) SOLAR CELL

(76) Inventors: Takayuki Negami, Osaka (JP); Teruaki Yamamoto, Ibaraki (JP)

(21) Appl. No.: 13/522,681

(22) PCT Filed: Jan. 20, 2011
(86) PCT No.: PCT/JP2011/051010

§ 371 Date: Jul. 17, 2012

(30) Foreign Application Priority Data
Jan. 21, 2010 (JP) 2010-011382

(51) Int. Cl. H01L 31/075

(52) U.S. Cl. 136/255

(57) ABSTRACT

A solar cell 10 of the present invention comprises a first semiconductor layer 13 of n-type or i-type, a second semiconductor layer 14 of n-type or i-type, and a third semiconductor layer 15 of p-type, and said first, second and third semiconductor layers are laminated in that order. Then, electron affinity x1 [eV] of said first semiconductor layer 13 and electron affinity x2 [eV] of said second semiconductor layer 14 satisfy a relationship of 0<(x2−x1)<=0.3.

### TECHNICAL FIELD

The invention relates to a solar cell, which has high energy conversion efficiency.

### BACKGROUND ART

It has been known that in regard to a heterojunction solar cell its characteristic depends on a difference in size between conductance band levels of an n-type semiconductor layer and a p-type semiconductor layer or a difference in size between valence band levels of the n-type semiconductor layer and the p-type semiconductor layer. In particular, when the p-type semiconductor layer is used as a light absorption layer, the difference in size between the conductance band levels (corresponding to electron affinity) of the n-type semiconductor layer and the p-type semiconductor layer has much influence on the characteristic of the solar cell.

For instance, “Prospects of wide-gapchalcopyrites for thin film photovoltaic modules”, Solar Energy Materials and Solar Cells, 49, p. 227 (1997), written by R. Herberholz, V. Nadenau, U. Ruhle, C. Koble, H. W. Schock and B. Dimmler, discloses that characteristic depending on discontinuity of conductance band levels of an n-type semiconductor layer and a p-type chalcopyrite-structure semiconductor layer is qualitatively-changed. Then, the document discloses that when a conductance band level of the n-type semiconductor layer is higher than that of the p-type semiconductor layer (electron affinity is small), a difference (conductance band offset) between conductance band levels thereof becomes a notch and does not have influence on characteristic of a solar cell. Also, the document discloses that in contrast, when the conductance band level of the n-type semiconductor layer is lower than that of the p-type semiconductor layer (electron affinity is large), the conductance band offset becomes a cliff and there is a loss of an open voltage.

On the other hand, Japanese Patent Application Laid-Open No. 2000-323733 discloses a range of a conductance band offset suitable for a solar cell. In the document, when electron affinity of an n-type semiconductor used as a window layer is denoted by x1 [eV] and electron affinity of a p-type semiconductor used as a light absorption layer is denoted by x2 [eV], the conductance band offset is denoted by x2−x1. When x2−x1 is positive, the conductance band offset becomes a notch. When x2−x1 is negative, the conductance band offset becomes a cliff. Then, in a range of 0<=x2−x1<0.5, high conversion efficiency can be provided. Then, in a range of x2−x1<0, the conductance band offset becomes a cliff and the cliff becomes a barrier to electrons injected from the n-type semiconductor. Therefore, the occurrence of recombination is increased in p-n junction interface and then a voltage is reduced. Then, in a range of 0.5<=x2−x1, the conductance band offset becomes a notch. However, because energy of the notch is too high, the notch becomes a barrier to carriers which are photoexcited in the p-type semiconductor and move to the n-type semiconductor, and thereby a current is reduced. In addition, the abovementioned document discloses that an oxide or a chalcogenide including Zn and Group 2 element, or an oxide or a chalcogenide including Zn and Group 13 element is used as an n-type semiconductor of a window layer for controlling such an electron affinity difference.

Then, Japanese Patent Application Laid-Open No. 8-125207 discloses a configuration of a solar cell that satisfies relationships of x1≈x2≈x3, φ1>φ2>φ3 and Eg1<Eg2<Eg3, when electron affinity, a work function and a band gap of a p-type semiconductor of a light absorption layer are denoted by x1, φ1 and Eg1, respectively, and electron affinity, a work function and a band gap of a semiconductor of an interlayer are denoted by x2, φ2 and Eg2, respectively, and electron affinity, a work function and a band gap of an n-type semiconductor of a window layer are denoted by x3, φ3 and Eg3, respectively. In this configuration, the interlayer is provided and thereby the occurrence of electron-hole recombination can be reduced in an interface between the conventional light absorption layer and window layer. In addition, the abovementioned document discloses that a compound of Group 12 element and Group 16 element, or a compound of Group 12 element and Mn and Group 16 element, or a compound of Group 12 element and Mg and Group 16 element is used as the semiconductor of the interlayer and the n-type semiconductor of the window layer satisfying the above-mentioned relationships.

As explained above, in the solar cell described in the Japanese Patent Application Laid-Open No. 8-125207, a relationship of x1≈x2≈x3 is satisfied. That is, the conductance band levels are set so as to be about equal to each other and an energy barrier is provided so that the valence band levels satisfy a relationship of Eg1+x1<Eg2+x2<Eg3+x3, and thereby the solar cell enhances electron-hole recombination is reduced in the interface. On the other hand, Japanese Patent Application Laid-Open No. 9-55519 discloses that valence band levels are set so as to be about equal to each other, and that is, an energy barrier is provided so that the valence band levels satisfy a relationship of Eg1+x1≈Eg2+x2≈Eg3+x3 and conductance band levels satisfy a relationship of x1>x2>x3, and thereby a solar cell can reduce electron-hole recombination in an interface. In addition, the abovementioned document discloses that CdS or ZnO, being a compound of Group 12 element and Group 16 element, is used as a semiconductor of an interlayer and an n-type semiconductor of a window layer satisfying the abovementioned relationships.

Then, Japanese Patent Application Laid-Open No. 9-199741 discloses a solar cell which is formed with lamination of a light absorption layer of a p-type semiconductor having electron affinity of x1, a work function of φ1 and a band gap of Eg1; an interlayer of an n-type semiconductor having electron affinity of x2, a work function of φ2 and a band gap of Eg2; a window layer of an n-type semiconductor having electron affinity of x3, a work function of φ3 and a band gap of Eg3; and a transparent electrode of an n-type semiconductor having electron affinity of x4, a work function of φ4 and a band gap of Eg4. Then, the solar cell satisfies relationships of x1≈x2≈x3≈x4, Eg1<Eg2<Eg3<Eg4, φ1>φ2>φ4 and φ2<=φ3<φ1, and a difference between φ2 and φ3 is less than or comparable to kT (about 26 [meV] at room temperature). In this configuration, not only photoelectric conversion between the light absorption layer and the interlayer but also photoelectric conversion between the window layer and the transparent electrode can be utilized. Therefore, high-efficiency of the solar cell can be achieved.

As disclosed in the Japanese Patent Application Laid-Open No. 2000-323733, when a conductance band offset (an electron affinity difference x2−x1) of p-type and n-type semiconductors is more than or equal to 0 [eV] but less than 0.5 [eV], the conductance band offset leads to the formation of the notch. Therefore, recombination of carriers injected from the n-type semiconductor is reduced in the interface. At this time, in a case where carriers of the p-type semiconductor of the light absorption layer have relatively-long lives, even if photoexcited carriers are retained in the notch, it has a small effect on the recombination due to the long life and does not inhibit transport of the photoexcited carriers. As a result, higher conversion efficiency can be provided. However, for instance, in a semiconductor having a wide band gap, generally there are many defect densities and thereby carriers have short lives. When such a semiconductor in which carriers have short lives is used as the light absorption layer and the conductance band offset is more than or equal to 0 [eV], it becomes a barrier to the photoexcited carriers. Then, even if retention times of the photoexcited carriers are short, the recombination occurs. Therefore, a photocurrent is significantly reduced and then conversion efficiency of the solar cell becomes insufficient. Likewise, in the solar cell described in the Japanese Patent Application Laid-Open No. 9-55519, a window layer of an n-type and an interlayer of an n-type become a barrier to photoexcited carriers. Then, even if retention times of the photoexcited carriers are short, the recombination occurs and a photocurrent is significantly reduced.

Then, in the Japanese Patent Application Laid-Open No. 8-125207 and the Japanese Patent Application Laid-Open No. 9-199741, electron affinities of layers are set so as to be substantively equal to each other. Therefore, the effects of the notch and cliff caused by the conductance band offset have been not considered, and in these heterojunction solar cells, there has been a problem that sufficient high-efficiency can not be provided.

Then, there are unresolved issues in a superstrate structure, which is formed with the lamination of a transparent electrode, a window layer, an interlayer or a buffer layer, and a light absorption layer, sequentially, on a translucent substrate. That is, the issues are interdiffusion of elements in the interlayer and the window layer, and acid and alkali resistances of the window layer, upon forming the interlayer. As an n-type semiconductor used for a window layer, an oxide including Group 12 element (Zn) and Group 2 element is described in the Japanese Patent Application Laid-Open No. 2000-323733. Then, a semiconductor formed of Group 12 element and Group 16 element and a semiconductor formed by dissolving Mn or Mg in those are described in the Japanese Patent Application Laid-Open No. 8-125207 and the Japanese Patent Application Laid-Open No. 9-55519. However, a compound including Group 12 element and Group 16 element, or an oxide consisting primarily of Group 12 element dissolves highly in acid. Thus, for instance, when the interlayer is formed onto the window layer by a production method using acid solution, there has been a problem that elution or interdiffusion in the interlayer and the window layer occurs.

### DISCLOSURE OF THE INVENTION

It is an object of the present invention to provide a solar cell, which can produce high energy conversion efficiency and which comprises a first semiconductor layer excelling in acid resistance and alkali resistance and being thermally stable and capable of preventing the occurrence of chemical reaction and elemental diffusion upon deposition of a second semiconductor layer.

A solar cell of the present invention comprises a first semiconductor layer 13 of n-type or i-type, a second semiconductor layer 14 of n-type or i-type, and a third semiconductor layer 15 of p-type, and said first, second and third semiconductor layers 13, 14, 15 are laminated in that order. According to a first aspect of the present invention, electron affinity x1[eV] of said first semiconductor layer 13 and electron affinity x2[eV] of said second semiconductor layer 14 satisfy a relationship of 0<(x2−x1)<=0.3. In the solar cell of the present invention, because a range of 0<(x2−x1) is set, the electron affinity of said first semiconductor layer 13 is smaller than that of said second semiconductor layer 14, and a conductance band level is high. Thus, an electric field is increased in a depletion layer of said third semiconductor layer 15, in regard to a p-n junction or a p-i-n junction formed between said first semiconductor layer 13 and a transparent electrode film formed of a low-resistivity n-type semiconductor or the like, and formed between said second and third semiconductor layers 14, 15. Therefore, the solar cell can reduce recombination of carriers, which are photoexcited in said third semiconductor layer 15, occurring near an interface between said second and third semiconductor layers 14, 15. Furthermore, because a range of (x2−x1)<=0.3 [eV] is set, the solar cell can prevent that a notch in said first semiconductor layer 13 grows too large and has a barrier to carrier transfer and then conversion efficiency is reduced. Therefore, the solar cell can produce high energy conversion efficiency, and such a solar cell can be provided.

In one embodiment, preferably, the electron affinity x1 [eV] of said first semiconductor layer 13 and electron affinity x3 [eV] of said third semiconductor layer 15 satisfy a relationship of 0<=(x3−x1)<0.3. In this case, the electric field is further increased in the depletion layer of said third semiconductor layer 15, and thus electron-hole recombination can be reduced and the conversion efficiency of the solar cell can be further enhanced.

A solar cell of the present invention comprises a first semiconductor layer 13 of n-type or i-type, a second semiconductor layer 14 of n-type or i-type and a third semiconductor layer 15 of p-type, and said first, second and third semiconductor layers 13, 14, 15 are laminated in that order. According to a second aspect of the present invention, electron affinity x1 [eV] of said first semiconductor layer 13, electron affinity x2 [eV] of said second semiconductor layer 14 and electron affinity x3 [eV] of said third semiconductor layer 15 satisfy a relationship of (x2−x1)>(x3−x1). Accordingly, an electron affinity difference, that is, a conductance band level difference, between said first and second semiconductor layers 13, 14 becomes larger than an electron affinity difference, that is, a conductance band level difference, between said first and third semiconductor layers 13, 15. For this reason, an electric field is increased in a depletion layer of said third semiconductor layer 15, and the solar cell can reduce recombination of carriers (electron-hole recombination), which are photoexcited in said third semiconductor layer, occurring in the depletion layer of said third semiconductor layer. Thus, the solar cell producing high conversion efficiency can be provided.

In one embodiment, preferably, said first semiconductor layer 13 is formed of an oxide of Group 5 element, and more preferably, said first semiconductor layer 13 consists primarily of Nb2O5. In this case, said first semiconductor layer 13 excels in acid resistance and alkali resistance and is thermally stable and is capable of preventing the occurrence of chemical reaction and elemental diffusion upon deposition of said second semiconductor layer, and then a solar cell comprising such a first semiconductor layer can be provided.

In one embodiment, preferably, said first semiconductor layer 13 is formed of an oxide of Group 4 element, and more preferably, said first semiconductor layer 13 consists primarily of an oxide expressed with a general formula: (Ti1−xZrx)O2 (0<x<1). In this case, said first semiconductor layer 13 excels in acid resistance and alkali resistance and is thermally stable and is capable of preventing the occurrence of chemical reaction and elemental diffusion upon deposition of said second semiconductor layer and furthermore is capable of controlling electron affinity with a composition ratio of Group 4 element, and then a solar cell comprising such a first semiconductor layer can be provided.

In one embodiment, preferably, said second semiconductor layer 14 consists primarily of a compound including Group 12 element and Group 16 element. In this case, said second semiconductor layer 14 obtains electron affinity suitable for said first and third semiconductor layers 13, 15, through combination of Group 12 element and Group 16 element. Then, a solar cell comprising such a second semiconductor layer can be provided.

In one embodiment, preferably, said second semiconductor layer 14 consists primarily of a compound including Group 13 element and Group 16 element. In this case, said second semiconductor layer 14 obtains electron affinity suitable for said first and third semiconductor layers 13, 15, through combination of Group 13 element and Group 16 element. Then, a solar cell comprising such a second semiconductor layer can be provided.

In one embodiment, preferably, said third semiconductor layer 15 consists primarily of a compound including Group 11 element, Group 13 element and Group 16 element, and more preferably, said third semiconductor layer has a chalcopyrite structure. In this case, said third semiconductor layer 15 has a high light absorption coefficient and is suitable for using as a light absorption layer. Then, a solar cell comprising such a third semiconductor layer can be provided.

In one embodiment, preferably, said third semiconductor layer 15 consists primarily of a compound including Group 12 element and Group 16 element. In this case, said third semiconductor layer is suitable for using as a light absorption layer. Then, a solar cell comprising such a third semiconductor layer can be provided.

In addition, according to the solar cell of the present invention, sunlight enters said first semiconductor layer 13, and then the light is absorbed in said third semiconductor layer 15, and thereby carriers are excited. For this reason, minimizing of the light absorption in said first and second semiconductor layers 13, 14 is effective for efficiency improvement of the solar cell. If the band gap Eg1 of said first semiconductor layer 13, the band gap Eg2 of said second semiconductor layer 14 and the band gap Eg3 of said third semiconductor layer 15 satisfy relationships of Eg1>Eg3 and Eg2>Eg3, a spectral range of sunlight absorbed in said first and second semiconductor layers 13, 14 is narrower than that absorbed in said third semiconductor layer 15, and thereby more photons enter said third semiconductor layer, and are absorbed in the layer. Accordingly, a photo current can be increased. Then, if each film thickness of said first and second semiconductor layers 13, 14 is sufficiently thin compared with its light absorption coefficient, amounts of light absorbed in said first and second semiconductor layers 13, 14 are low even in a condition other than the above-mentioned conditions of the band gaps. Hence, the amount of light and the number of photons, entering said third semiconductor layer 15, are not extremely decreased.

### BRIEF DESCRIPTION OF THE DRAWINGS

Preferred embodiments of the invention will now be described in further details. Other features and advantages of the present invention will become better understood with regard to the following detailed description and accompanying drawings where:

FIG. 1 is a schematic cross-section diagram of one example of a solar cell according to an embodiment of the present invention;

FIG. 2 is a diagram showing one example of energy band structures of first, second and third semiconductor layers in said solar cell according to said embodiment of the present invention;

FIG. 3 is a diagram showing one example of variation of conversion efficiency with respect to an electron affinity difference (x2−x1) between said first and second semiconductor layers, when an electron affinity difference (x3−x1) between said first and third semiconductor layers is set as a parameter, in said solar cell according to said embodiment of the present invention;

FIG. 4 is a diagram showing one example of variation of a band gap with respect to a Zr/(Ti+Zr) ratio x of a (Ti1−xZrx)O2 film in said solar cell according to said embodiment of the present invention; and

FIG. 5 is a diagram showing one example of variation of conversion efficiency with respect to a Zr/(Ti+Zr) ratio x, when a (Ti1-xZrx)O2 film is used for said first semiconductor layer in said solar cell according to said embodiment of the present invention.

### BEST MODE FOR CARRYING OUT THE INVENTION

A solar cell according to an embodiment of the present invention will be explained below.

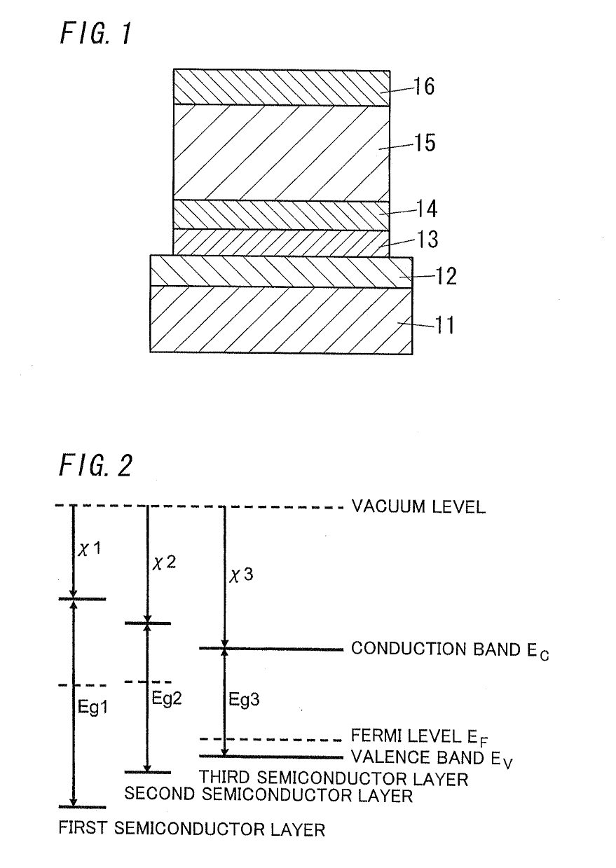

FIG. 1 is a diagram showing one example of a solar cell 10 of the present invention. A transparent electrode film 12 of n-type semiconductor is formed onto one surface of a substrate 11. Onto one surface of transparent electrode film 12 opposite the substrate 11, a first semiconductor layer 13 of n-type or i-type, a second semiconductor layer 14 of n-type or i-type and a third semiconductor layer 15 of p-type are laminated in that order. Then, a back side electrode 16 is formed onto third semiconductor layer 15.

Substrate 11 is formed of a glass, a translucent resin or the like, and such a substrate can be used.

Transparent electrode film 12 of n-type semiconductor can be formed of a metallic oxide film. Then, for instance, SnO2:F, ZnO:Al, ZnO:Ga, IXO(In2O3:X, X is Sn, Mn, Mo, Ti or Zn), or the like can be used as such a metallic oxide. Then, the metallic oxide film may comprise a plurality of films, and transparent electrode film 12 may be a laminated film obtained by lamination of the plurality of films.

First semiconductor layer 13 of n-type or i-type is used for a window layer in solar cell 10, and preferably, is formed of a metallic oxide including Group 5 element. Here, in a high-resistivity semiconductor, it is difficult to distinguish an n-type semiconductor from an i-type semiconductor. As a result, first semiconductor layer 13 is desired to be a semiconductor layer other than p-type.

The metallic oxide including Group 5 element may include Nb2O5, (Nb1−xVx)2O5 (0<=x<=1) obtained by dissolving V or the like. In particular, preferably, first semiconductor layer consists primarily of Nb2O5.

Also, preferably, first semiconductor layer 13 is formed of a metallic oxide including Group 4 element. The metallic oxide including Group 4 element may include (Ti1−xZrx)O2 (0<x<1) or the like. In particular, preferably, first semiconductor layer consists primarily of (Ti1−xZrx)O2.

In this case, the primary component means a component except for a dopant and an impurity. Generally, a ratio of a primary component in a semiconductor layer is more than or equal to 99 atomic percent. However, in an oxide, there is a case where a ratio of the dopant is 10 atomic percent. As a result, a ratio of the primary component is in a range of more than or equal to 90 atomic percent.

First semiconductor layer 13 may be a laminated film obtained by lamination of a plurality of different semiconductor thin films. In this case, preferably, a semiconductor thin film laminated in a side closest to second semiconductor layer 14 is formed of a metallic oxide including Group 5 element or Group 4 element. Such a laminated film may include, for instance, a film obtained by means of laminating an Nb2O5 thin film onto a TiO2 thin film.

In this way, when first semiconductor layer 13 is formed of an oxide represented by Nb2O5 or (Ti1−xZrx)O2 (0<x<1), the occurrence of chemical reaction and elemental diffusion can be prevented upon deposition of second semiconductor layer 14 onto first semiconductor layer 13 under general temperature conditions (less than or equal to 600 degrees C.) in production process of a solar cell. Particularly, electron affinity can be controlled by a composition ratio x of Group 4 element, in (Ti1−xZrx)O2 and then efficiency improvement of the solar cell can be achieved. Therefore, the use of (Ti1−xZrx)O2 is preferred.

Second semiconductor layer 14 of n-type or i-type is used for an interlayer or a buffer layer in solar cell 10. Then, in a high-resistivity semiconductor, it is difficult to distinguish an n-type semiconductor from an i-type semiconductor. Therefore, second semiconductor layer 14 is desired to be a semiconductor layer other than p-type. Second semiconductor layer 14 is formed of a semiconductor including, for instance, Group 12 element and Group 16 element. In particular, preferably, second semiconductor layer 14 consists primarily of a semiconductor including Group 12 element and Group 16 element. The semiconductor of Group 12 element and Group 16 element may include Zn(O,S), CdS or the like. Then, second semiconductor layer 14 may be formed of a semiconductor including Group 13 element and Group 16 element. In particular, preferably, second semiconductor layer 14 consists primarily of a semiconductor including Group 13 element and Group 16 element. The semiconductor of Group 13 element and Group 16 element may include In2S3, Ga2S3 or the like. Then, second semiconductor layer 14 may be formed of Zn1−xMgxO (0<=x<1).

Third semiconductor layer 15 of p-type is used for a light absorption layer in solar cell 10. Third semiconductor layer 15 can be formed of a semiconductor having a chalcopyrite structure including Group 11 element, Group 13 element and Group 16 element. In particular, preferably, third semiconductor layer 15 consists primarily of a semiconductor having a chalcopyrite structure including Group 11 element, Group 13 element and Group 16 element. The semiconductor of this chalcopyrite structure may include (Cu1−xAgx)(In1−yGay)(S1−zSez)2, (Cu1−xAgx)(In1−yAly)(S1−zSez)2, (Cu1−xAgx)(Ga1-yAly)(S1−zSez)2, (Cu1−xAgx)(In1−yGay)(S1−zTez)2, (Cu1−x Agx)(In1−yAly)(S1−zTez)2, (Cu1−xAgx)(Ga1−yAly)(S1−zTez)2, (Cu1−xAgx)(In 1−yGay)(Se1−zTez)2, (Cu1−xAgx)(In1−yAly)(Se1−zTez)2, (Cu1−xAgx)(Ga1−yAly) (Se1−zTez)2, or the like (0<=x<=1, 0<=y<=1, 0<=z<=1). Also, preferably, third semiconductor layer 15 is formed of a semiconductor including Group 12 element and Group 16 element. The semiconductor may include (Cd1−xZnx)(Te1−ySey), (Cd1−xZnx)(Te1−ySy), (Cd1−xZnx) (Se1−ySy), or the like (0<=x<=1, 0<=y<=1).

Back side electrode 16 can be formed of a metallic film. For instance, Au, Pt or Ag can be used for the metal. Also, back side electrode 16 can be formed of a carbon. When, for instance, as a top solar cell in a tandem solar cell, it is necessary to transmit sunlight having a long wavelength which is not absorbed in third semiconductor layer 15 of the light absorption layer, it is preferred that back side electrode 16 is formed of a conductive oxide film having translucency. Then, for instance, the electrode 16 can be formed of a metallic oxide film similar to transparent electrode film 12, an Ag2O film, or an oxide film including a copper, such as Cu2O or CuSr2O4.

A numerical simulation of the characteristics was performed with respect to solar cell 10 obtained by combination of first, second and third semiconductor layers 13, 14, 15 having band structures shown in FIG. 2, in one example of solar cell 10 formed as described above. The numerical simulation was performed by finite difference method using Poisson equation and electric current equation of continuity. Here, solar cell 10 was formed by laminating, from a light incidence side, substrate 11, transparent electrode film 12 of n-type, first semiconductor layer 13 of n-type, second semiconductor layer 14 of n-type, third semiconductor layer 15 of p-type, and back side electrode 16 of the metallic film. In regard to first semiconductor layer 13 of n-type, a physical property of ZnO was used. In regard to second semiconductor layer 14 of n-type, a physical property of In2S3 was used. Then, third semiconductor layer 15 of p-type was used for a light absorption layer and its material was CuInS2. Electron lifetime and hole lifetime of the CuInS2 were set into short times being 1 [ns] and 0.2 [ns], respectively. Then, in regard to transparent electrode film 12 of n-type, a physical property of ZnO:Al was used, and its electron affinity was set to be equal to that of first semiconductor layer 13. Then, on the assumption that an ohmic contact would be formed between back side electrode 16 of the metallic film and a CuInS2 film of third semiconductor layer 15, a material of the metallic film was selected.

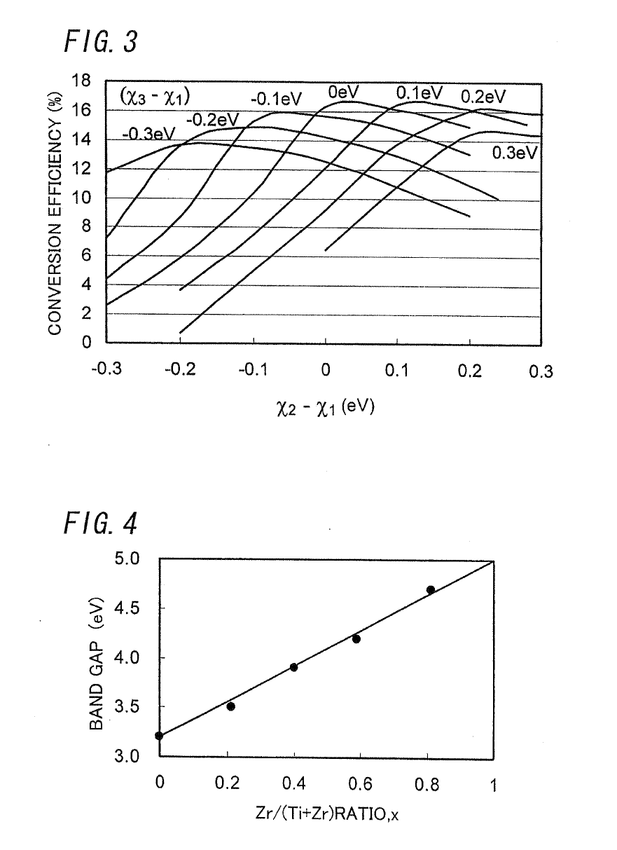

Under the abovementioned configuration, electron affinities x1, x2 of first and second semiconductor layers 13, 14 were changed and a difference (x3−x1) between electron affinities x3, x1 of third and first semiconductor layers 15, 13 were used as a parameter. In this case, as a numerical simulation outcome, FIG. 3 shows variation of conversion efficiency of solar cell 10 with respect to a difference (x2−x1) between the electron affinities x2, x1. As can be expected from FIG. 3, high conversion efficiency can be provided in a range of 0 [eV]<x2−x1<=0.3 [eV] with respect to peak values of curve lines of (x3−x1) other than a curve line of (x3−x1)=0.3 [eV]. Also, as can be expected from FIG. 3, high conversion efficiency can be provided in a range of 0[eV]<=x3−x1<0.3 [eV] with respect to a parameter of (x3−x1).

As described above, a solar cell having high conversion efficiency can be provided by setting (x2−x1) in a range of 0 [eV]<x2−x1<=0.3 [eV]. In a case of 0 [eV]<x2−x1, electron affinity of first semiconductor layer 13 is smaller than that of second semiconductor layer 14. Thus, an electric field is increased in a depletion layer of third semiconductor layer 15, in regard to a p-n junction or a p-i-n junction, formed between transparent electrode film 12 and first semiconductor layer 13, and formed between second and third semiconductor layers 14, 15. Therefore, the solar cell can reduce recombination of carriers, which are photoexcited in third semiconductor layer 15, occurring within the depletion layer of third semiconductor layer 15. Then, in a case of x2−x1<=0.3 [eV], the solar cell can prevent that a notch in first semiconductor layer grows too large and the notch has a barrier to carrier transfer.

Then, as described above, it is preferred that (x2−x1) is set so as to be in a range of 0 [eV]<x2−x1<0.3 [eV] and (x3−x1) is set so as to be in a range of 0 [eV]<=x3−x1<0.3 [eV]. In this case, a solar cell producing higher conversion efficiency can be provided. That is, in a case of 0 [eV]<=x3−x1, electron affinity of first semiconductor layer 13 is smaller than that of second semiconductor layer 14, and furthermore an electric field is increased in a depletion layer of third semiconductor layer 15. Therefore, the solar cell can reduce recombination of carriers, which are photoexcited in third semiconductor layer 15, occurring within the depletion layer of third semiconductor layer 15. Then, in a case of x3−x1<0.3 [eV], the solar cell can prevent that a notch in first semiconductor layer 13 grows too large and the notch has a barrier to carrier transfer.

Then, as can be expected from FIG. 3, in regard to each curve line of (x3−x1), a value of (x2−x1) having a peak efficiency is larger than a value of (x3−x1). For instance, in a curve line of (x3−x1)=0 [eV], a value of (x2−x1) having a peak efficiency is about 0.03 [eV], and that is, is larger than a value of (x3−x1). Then, it is found that when this relationship satisfies (x2−x1)>(x3−x1) without being limited to the abovementioned ranges of (x2−x1) and (x3−x1), a solar cell having high conversion efficiency can be provided. For instance, in a curve line of (x3−x1)=−0.1 [eV], upon (x2−x1)=−0.06 [eV], a solar cell having conversion efficiency of 16[%] can be provided. Then, in a case of (x2−x1)>(x3−x1), conversion efficiency has a low change for a change of (x2−x1). Thereby, second semiconductor layer 14 has high design tolerance, and then this has an advantage in production of a solar cell having high conversion efficiency.

As described above, through (x2−x1)>(x3−x1), an electron affinity difference, that is, a conductance band level difference, between first and second semiconductor layers 13, 14 is larger than an electron affinity difference, that is, a conductance band level difference, between first and third semiconductor layers 13, 15. For this reason, an electric field is increased in a depletion layer of third semiconductor layer 15. Thus, the solar cell can reduce recombination of carriers, which are photoexcited in third semiconductor layer 15, occurring in the depletion layer of third semiconductor layer 15, and then the solar cell having high energy conversion efficiency can be provided.

Next, the present invention will be explained specifically through the following Test Examples 1 to 3.

### TEST EXAMPLE 1

In the present Test Example, Practical Example 1 of the present invention was prepared and will be explained below. Then, Comparison Example 1 was prepared for being compared with the Practical Example 1.

First, in the Practical Example 1 of the present invention, a soda-lime glass was used as substrate 11. Then, n-type transparent electrode film 12 of a SnO2:F film was deposited onto the glass so as to have a film thickness of about 0.8 [μm], by Thermo Chemical Vapor Deposition (CVD) method. Onto the SnO2:F film, first semiconductor layer 13 of an Nb2O5 film was deposited so as to have a film thickness of about 0.1 [μm], by sputtering method. In regard to the sputtering method, a sintered compact of Nb2O5 was used for a target, and then RF 400 [W] was applied to the target in an Ar atmosphere.

Next, onto the Nb2O5 film, second semiconductor layer 14 of an In2S3 film was deposited so as to have a film thickness of about 0.1 [μm], by spray coating pyrolysis method. In regard to the spray coating pyrolysis method, an aqueous solution of InCl3 of 2 [mmol/l] and thiourea of 6 [mmol/l] was sprayed onto the Nb2O5 film heated to substrate temperature of 370 degrees C. Here, although the aqueous solution of InCl3 and thiourea has acidic property, the Nb2O5 film has high resistance to acids. Therefore, elution or the like does not occur.

Then, onto the In2S3 film, p-type third semiconductor layer 15 of a CuInS2 film, used as a light absorption layer, was deposited so as to have a film thickness of about 2 [μm], by spray coating pyrolysis method. In regard to the spray coating pyrolysis method, an aqueous solution of CuCl2 of 2 [mmol/l], InCl3 of 2 [mmol/l] and thiourea of 6 [mmol/l] was sprayed onto the In2S3 film heated to substrate temperature of 375 degrees C.

Here, when electron affinity of Nb2O5 being first semiconductor layer 13 is denoted by x1 and electron affinity of In2S3 being second semiconductor layer 14 is denoted by x2, a difference x2−x1 is about 0.2 [eV].

Then, when electron affinity of CuInS2 being third semiconductor layer 15 is denoted by x3, a difference x3−x1 is about 0 [eV].

Then, an Au film of back side electrode 16 was formed so as to have a film thickness of about 0.2 [μm], by evaporation method, and a solar cell was made.

Then, artificial sunlight (1 [kW/m2], air mass 1.5) was emitted to the solar cell made in the above way, and current-voltage characteristics was measured. As a result, conversion efficiency of the made solar cell was 8.1[%].

In addition, in the present Practical Example, first semiconductor layer 13 was formed of the Nb2O5 film. However, for instance, first semiconductor layer 13 can be also formed of a (Nb1−xVx)2O5 film (0<=x<=1) obtained by dissolving V, with respect to third semiconductor layer 15 having large electron affinity. In this case, the electron affinity difference (x3−x1) between these layers 13, 15 can be controlled by the solid solution ratio of V. Therefore, first semiconductor layer 13 can be provided so that the electron affinity difference (x3−x1) is suitable for a solar cell.

Then, not only in the present Test Example 1, but also in all Test Examples 1 to 3, first semiconductor layer 13 was formed by the sputtering method. However, the production method is not limited to the sputtering method, and then first semiconductor layer 13 can be also formed by other evaporation method, spray coating decomposition method, or CVD method.

Next, in Comparison Example 1, a TiO2 film of first semiconductor layer 13 was deposited so as to have a film thickness of about 0.1 [μm], by the sputtering method, and in regard to other configurations, a solar cell was made in the same manner as Practical Example 1. In regard to the above sputtering method, a sintered compact of TiO2 was used for a target, and then RF 400 [W] was applied to the target in an Ar atmosphere.

Here, when electron affinity of TiO2 being first semiconductor layer 13 is denoted by x1 and electron affinity of In2S3 being second semiconductor layer 14 is denoted by x2, a difference x2−x1 is about −0.1[eV]. Then, when electron affinity of CuInS2 being third semiconductor layer 15 is denoted by x3, a difference x3−x1 is about −0.3[eV].

Then, artificial sunlight (1 [kW/m2], air mass 1.5) was emitted to the solar cell made in the above way, and current-voltage characteristics was measured. As a result, conversion efficiency of the made solar cell was 7.0[%].

As can be expected from the above-mentioned results, the solar cell in Practical Example 1 has high conversion efficiency compared with the solar cell in Comparison Example 1. Also, the solar cell in Practical Example 1 had almost no change of an open voltage compared with the solar cell in Comparison Example 1. However, short-circuit current and fill factor were increased.

In regard to this, electron affinity of Nb2O5 being first semiconductor layer 13 is smaller than electron affinity of In2S3 being second semiconductor layer 14. Therefore, it is considered that an electric field was increased in a depletion layer of CuInS2 being third semiconductor layer 15, and recombination of photoexcited carriers was reduced in the depletion layer, and thereby short-circuit current and fill factor were increased.

As can be expected from the above, the configuration in Practical Example 1 of the present invention has an advantage in conversion efficiency improvement of a solar cell.

### TEST EXAMPLE 2

In the present Test Example, five solar cells were prepared, and then in regard to (Ti1−xZrx)O2 films used for first semiconductor layers 13 thereof, content rates x of Zr were set into 0, 0.2, 0.4, 0.6, 0.8, respectively.

Then, a soda-lime glass was used as substrate 11 in each of the five solar cells. Then, transparent electrode film 12 of a SnO2:F film was deposited onto the glass so as to have a film thickness of about 0.8 [μm], by CVD method. Onto the SnO2:F film, first semiconductor layer 13 of a (Ti1−xZrx)O2 film was deposited so as to have a film thickness of about 0.1 [μm], by sputtering method. In regard to the sputtering method, in order to make films thereof by changing the content rates x of Zr, metallic targets of Ti and Zr were used and then, by changing the power applied to Ti and Zr, the (Ti1−xZrx)O2 film in each solar cell was deposited in Ar and O2 atmosphere (Ar:02=4:1) at substrate temperature of 200 degrees C.

Next, Onto the (Ti1−xZrx)O2 film, second semiconductor layer 14 of a Ga2S3 film was deposited so as to have a film thickness of about 0.1 [μm], by spray coating pyrolysis method. In regard to the spray coating pyrolysis method, an aqueous solution of GaCl3 of 2 [mmol/l] and thiourea of 6 [mmol/l] was sprayed onto the (Ti1−xZrx)O2 film heated to substrate temperature of 400 degrees C. Here, although the aqueous solution of GaCl3 and thiourea has acidic property, the (Ti1−xZrx)O2 film has high resistance to acids. As a result, elution or the like does not occur.

Then, onto the Ga2S3 film, p-type third semiconductor layer 15 of a Cu(In0.8Ga0.2)S2 film, used as a light absorption layer, was deposited so as to have a film thickness of about 2 [μm], by spray coating pyrolysis method. In regard to the spray coating pyrolysis method, an aqueous solution of CuCl2 of 2 [mmol/l], InCl3 of 1.6 [mmol/l], GaCl3 of 0.4 [mmol/l] and thiourea of 6 [mmol/l] was sprayed onto the Ga2S3 film heated to substrate temperature of 400 degrees C.

Then, an Au film of back side electrode 16 was formed so as to have a film thickness of about 0.2 [μm], by evaporation method, and in this way, each solar cell was made.

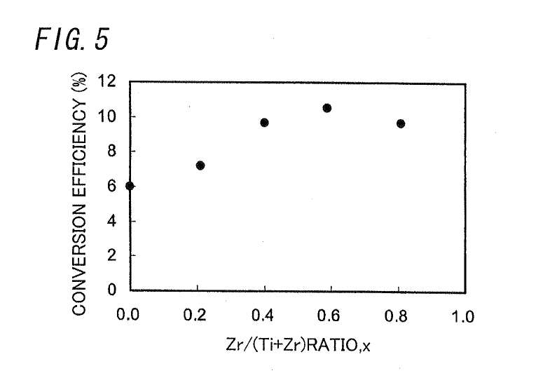

Here, as described above, in formation of second semiconductor layer 14, a content rate x of Zr (=Zr/(Ti+Zr)) in a (Ti1−xZrx)O2 film was changed by means of changing the power applied to metallic targets of Ti and Zr. Then, in this case, FIG. 4 shows variation of a band gap with respect to the content rate x. As can be expected from FIG. 4, the band gap increases in almost a linear fashion with increase in the content rate x. Then, it is considered that electron affinity of ZrO2 (x=1) is smaller than that of TiO2 (x=0) and then the sum of energies of the electron affinity and a band gap of ZrO2 (a valance band level) is larger than that of TiO2 and thereby the electron affinity also decreases in almost a linear fashion with respect to the content rate x of Zr.

Artificial sunlight (1 [kW/m2], air mass 1.5) was emitted to the five solar cells made in the above way, and FIG. 5 shows conversion efficiencies thereof obtained by means of measuring current-voltage characteristics. Here, a solar cell using TiO2 of x=0 is equivalent to a conventional solar cell. As can be expected from FIG. 5, the conversion efficiency increases with increase in the rate x till x=0.4. Then, the conversion efficiency has almost no change from x=0.4 to x=0.8. In regard to this, it is considered that the electron affinity difference (x2−x1) between the (Ti1−xZrx)O2 film of first semiconductor layer 13 and the Ga2S3 film of second semiconductor layer 14 is changed from negative to positive with increase in the rate x, and the electron affinity difference (x3−x1) between the (Ti1−xZrx)O2 film of first semiconductor layer 13 and the Cu(In0.8Ga0.2)S2 film of third semiconductor layer 15 is also changed from negative to positive, and thereby the abovementioned no change from x=0.4 to x=0.8 corresponds to the shift to the right side's curve lines in the numerical simulation outcome of FIG. 3. Thus, it is found that high conversion efficiency can be obtained by means of controlling the content rate x of Zr in the (Ti1−xZrx)O2 film.

Here, although high conversion efficiency was obtained in a range of 0.4<=x<=0.8, a suitable range of the content rate x of Zr changes in response to the electron affinity difference between first and second semiconductor layers 13, 14 and the electron affinity difference between first and third semiconductor layers 13, 15. However, because in the (Ti1−xZrx)O2 film the electron affinity being linked to the band gap can be controlled by changing the content rate x of Zr, in a heterojunction solar cell a suitable semiconductor layer can be provided.

### TEST EXAMPLE 3

In the present Test Example, Practical Example 2 of the present invention was prepared and will be explained below. Then, Comparison Example 2 was prepared for being compared with the Practical Example 2.

First, in Practical Example 2 of the present invention, a soda-lime glass was used as substrate 11. Then, transparent electrode film 12 of a SnO2:F film was deposited onto the glass so as to have a film thickness of about 0.8 [μm], by Thermo Chemical Vapor Deposition (CVD) method. Onto the Sn02:F film, first semiconductor layer 13 of an (Ti0.3Zr0.7)O2 film was deposited so as to have a film thickness of about 0.1 [μm], by sputtering method. In regard to the sputtering method, a sintered compact of (Ti0.3 Zr0.7)O2 was used for a target, and then the power of 500 [W] was applied to the target in an Ar atmosphere, and substrate temperature was set at 200 degrees C.

Next, onto the (Ti0.3Zr0.7)O2 film, second semiconductor layer 14 of a CdS film was deposited so as to have a film thickness of about 0.1 [μm], by chemical separation method. In regard to the chemical separation method, an aqueous solution of Cd nitrate, thiourea and ammonia was heated to temperature of about 80 degrees C., and then a substrate was soaked in the aqueous solution. Here, although the aqueous solution of Cd nitrate, thiourea and ammonia has alkaline property, the (Ti0.3Zr0.7)O2 film has high resistance to alkali. As a result, elution or the like does not occur.

Then, onto the CdS film, p-type third semiconductor layer 15 of a CdTe film, used as a light absorption layer, was deposited so as to have a film thickness of about 5 [μm], by close spaced sublimation method. In regard to the close spaced sublimation method, a source of powdered CdTe, paste CdTe or the like was put to a tray, and a substrate was closely located on the tray so that the CdS film faces to the source, and CdTe was sublimated by heating the source at high temperature, and furthermore a CdCl2 solution was applied, and recrystallization of the CdTe film was performed by heating at temperature of about 400 degrees C.

Then, back side electrode 16 of a carbon paste including Cu was deposited onto the CdTe film by coating, and in this way, a solar cell was made.

Then, artificial sunlight (1 [kW/m2], air mass 1.5) was emitted to the solar cell made in the above way, and current-voltage characteristics was measured. As a result, conversion efficiency of the made solar cell was 13[%].

Next, in Comparison Example 2, first semiconductor layer 13 of a non-doped SnO2 film was deposited, and in regard to other configurations, a solar cell was made in the same manner as Practical Example 2.

Then, artificial sunlight (1 [kW/m2], air mass 1.5) was emitted to the solar cell made in the above way, and current-voltage characteristics was measured. As a result, conversion efficiency of the made solar cell was 12[%].

As the abovementioned result, conversion efficiency 13[%] of the solar cell in Practical Example 2 was improved by about 10[%] with respect to conversion efficiency 12[%] of the solar cell in Comparison Example 2. In particular, short-circuit current and fill factor were improved. In regard to this, the following reason can be thought. In Comparison Example 2, an electron affinity difference (x2−x1) between SnO2 of first semiconductor layer 13 and CdS of second semiconductor layer 14 is almost −0.7 [eV] and a large cliff is formed, and furthermore an electron affinity difference (x3−x1) between SnO2 of first semiconductor layer 13 and CdTe of third semiconductor layer 15 is almost −0.9 [eV], and that is, large differences occur. On the other hand, in Practical Example 2, an electron affinity difference (x2−x1) between (Ti0.3Zr0.7)O2 of first semiconductor layer 13 and CdS of second semiconductor layer 14 is almost 0.2 [eV], and an electron affinity difference (x3−x1) between (Ti0.3Zr0.7)O2 of first semiconductor layer 13 and CdTe of third semiconductor layer 15 is almost 0 [eV], and that is, the electron affinity differences are in almost a suitable range in the numerical simulation outcome of FIG. 3, and this is the reason of the above improvement.

As explained above, in the present invention, the electron affinity differences between first, second and third semiconductor layers 13, 14, 15 are controlled so as to be in a suitable range, and thereby a solar cell having high conversion efficiency can be provided.

Then, although all solar cells described in Test Examples 1 to 3 have superstrate structures and sunlight enters glass surfaces of substrates thereof, the present invention is not limited to such a structure. For instance, a Mo film of a back side electrode is formed onto a glass substrate, and a Cu(In,Ga)Se2 film of p-type third semiconductor layer 15 being a light absorption layer is formed onto it, and a Zn(O,S) film of second semiconductor layer is formed onto it, and a (Ti1−xZrx)O2 film of first semiconductor layer 13 is formed onto it, and a ZnO:Al film of a transparent electrode film is formed onto it, and also in a solar cell having such a substrate structure, the present invention is effective in improvement of conversion efficiency. In this case, for instance, if a band gap of the Cu(In,Ga)Se2 film is almost 1.2 [eV], in regard to the (Ti1−xZrx)O2 film of first semiconductor layer 13 the content rate x of Zr is set in a range of 0.2 to 0.5 and thereby an electron affinity difference between the (Ti1−Zrx)O2 film and the Cu(In,Ga)Se2 film can be controlled in a range suitable for the invention. In addition, also in regard to the Zn(O,S) film of second semiconductor layer 14, an electron affinity difference can be controlled in a range suitable for the invention.

Although the present invention has been described with reference to certain preferred embodiments, numerous modifications and variations can be made by those skilled in the art without departing from the true spirit and scope of this invention, namely claims.

1. A solar cell, comprising a first semiconductor layer of n-type or i-type, a second semiconductor layer of n-type or i-type, and a third semiconductor layer of p-type, said first, second and third semiconductor layers being laminated in that order,
wherein electron affinity x1 [eV] of said first semiconductor layer and electron affinity x2 [eV] of said second semiconductor layer satisfy a relationship of 0<(x2−x1)<=0.3.

2. The solar cell as claimed in claim 1, wherein the electron affinity x1 [eV] of said first semiconductor layer and electron affinity x3 [eV] of said third semiconductor layer satisfy a relationship of 0<=(x3−x1)<0.3.

3. A solar cell, comprising a first semiconductor layer of n-type or i-type, a second semiconductor layer of n-type or i-type, and a third semiconductor layer of p-type, said first, second and third semiconductor layers being laminated in that order,
wherein electron affinity x1 [eV] of said first semiconductor layer, electron affinity x2 [eV] of said second semiconductor layer and electron affinity x3 [eV] of said third semiconductor layer satisfy a relationship of (x2−x1)>(x3−x1).

4. The solar cell as claimed in any one of claims 1-3, wherein said first semiconductor layer is formed of an oxide of Group 5 element.

5. The solar cell as claimed in claim 4, wherein said first semiconductor layer consists primarily of Nb2O5.

6. The solar cell as claimed in any one of claims 1-3, wherein said first semiconductor layer is formed of an oxide of Group 4 element.

7. The solar cell as claimed in claim 6, wherein said first semiconductor layer consists primarily of an oxide expressed with a general formula: (Ti1−xZrx)O2 (0≦x≦1).

8. The solar cell as claimed in any one of claims 1-3, wherein said second semiconductor layer consists primarily of a compound including Group 12 element and Group 16 element.

9. The solar cell as claimed in any one of claims 1-3, wherein said second semiconductor layer consists primarily of a compound including Group 13 element and Group 16 element.

10. The solar cell as claimed in any one of claims 1-3, wherein said third semiconductor layer consists primarily of a compound including Group 11 element, Group 13 element and Group 16 element.

11. The solar cell as claimed in claim 10, wherein said third semiconductor layer has a chalcopyrite structure.

12. The solar cell as claimed in any one of claims 1-3, wherein said third semiconductor layer consists primarily of a compound including Group 12 element and Group 16 element.
